(19) United States
(12) Patent Application Publication
(10) Pub. No.: US 2016/0056350 A1
(43) Pub. Date: Feb. 25, 2016

(54) LED ENCAPSULATION STRUCTURE

(71) Applicant: HON HAI PRECISION INDUSTRY CO., LTD., New Taipei (TW)

(72) Inventors: GWO-YAN HUANG, New Taipei (TW); CHIEN-LIANG CHEN, New Taipei (TW); DER-HO CHI, New Taipei (TW)

(21) Appl. No.: 14/573,536

(22) Filed: Dec. 17, 2014

(30) Foreign Application Priority Data
Aug. 20, 2014 (TW) 103128565

(51) Int. Cl. H01L 33/52; H01L 33/60

(52) U.S. Cl. CPC H01L 33/52; H01L 33/60

(57) ABSTRACT

An LED encapsulation structure includes a reflective cup, a positive electrode plate, and a negative electrode plate. The reflective cup has a light emitting surface, a bottom surface opposite to the light emitting surface, two parallel first sides, and two parallel second sides. The positive electrode plate includes a first weld, a second weld, and a bent portion interconnecting with the first weld and the second weld. The negative electrode plate includes a third weld, a fourth weld, and a second bent portion interconnecting with the third weld and the fourth weld. The first weld and the third weld are positioned on one first side, and spaced from each other. The second weld and the fourth weld are positioned on the bottom surface.

### FIELD

The subject matter herein generally relates to light emitting diode (LED) encapsulation structures and in particular to surface-mount device (SMD) LED encapsulation structures.

### BACKGROUND

LEDs are extensively applied to illumination devices due to high brightness, low working voltage, low power consumption, compatibility with integrated circuitry, simple driving operation, long life and other factors.

### BRIEF DESCRIPTION OF THE DRAWINGS

Implementations of the present technology will now be described, by way of example only, with reference to the attached figures.

FIG. 1 is an isometric view of an embodiment of an LED encapsulation structure.

FIG. 2 is similar to FIG. 1, but viewed from another angle.

FIG. 3 is an isometric view of the LED encapsulation structures assembled on a printed circuit board in a first state of use.

FIG. 4 is similar to FIG. 3, but showing the LED encapsulation structures assembled on the printed circuit board in a second state of use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

A light emitting diode (LED) encapsulation structure can include a reflective cup, a positive electrode plate positioned on the reflective cup, and a negative electrode plate positioned on the reflective cup and spaced from the positive electrode plate. The reflective cup can have a light emitting surface, a bottom surface opposite to the light emitting surface, two parallel first sides interconnecting with the light emitting surface and the bottom surface, and two parallel second sides interconnecting with the light emitting surface, the bottom surface and two the first sides. The positive electrode plate can include a first weld positioned on one first side, a second weld positioned on the bottom surface, and a first bent portion interconnecting with the first weld and the second weld. The negative electrode plate can include a third weld positioned on the same first side as the first weld and spaced from the first weld, a fourth weld positioned on the bottom surface and spaced from the second weld, and a second bent portion interconnecting with the third weld and the fourth weld.

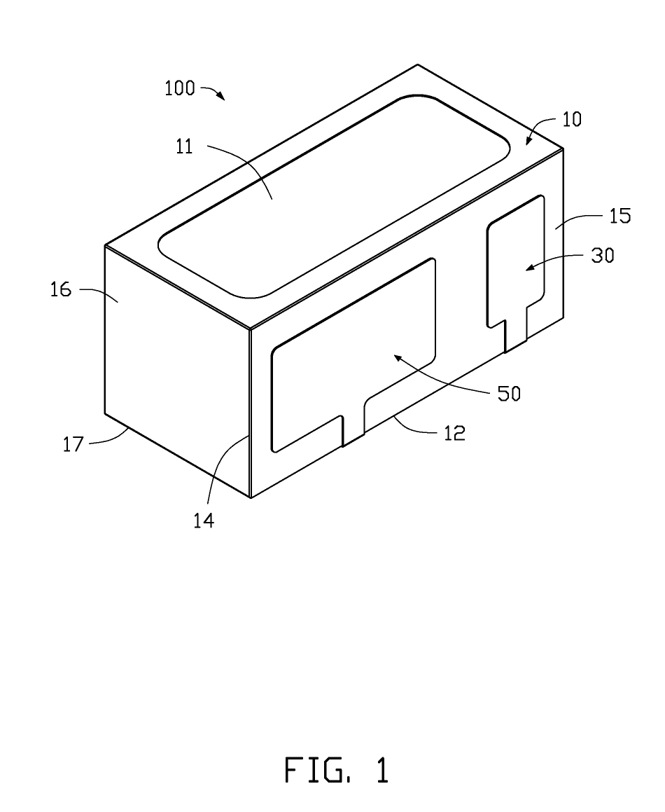

FIGS. 1 to 3 illustrate an embodiment of an LED encapsulation structure 100. The LED encapsulation structure 100 can include a reflective cup 10, an LED chip (not shown) received in the reflective cup 10, a positive electrode plate 30, and a negative electrode plate 50. The positive electrode plate 30 and the negative electrode plate 50 can be positioned on the reflective cup 10, respectively. In at least one embodiment, the LED encapsulation structure 100 can be welded to the printed circuit board (PCB) 70 by a surface mounting weld method.

The reflective cup 10 can be substantially rectangular. The reflective cup 10 can include a light emitting surface 11, a bottom surface 13 opposite to the light emitting surface 11, two parallel first sides 15 configured to interconnect with the light emitting surface 11 and the bottom surface 13, and two parallel second sides 16 configured to interconnect with the light emitting surface 11, the bottom surface 13, and two first sides 15. The reflective cup 10 can have a reflective inner surface (not shown) which is configured to reflect light emitted from the LED chip to the light emitting surface 11. Each first side 15 can include two parallel first edges 12, and two parallel second edges 14 configured to interconnect with the two first edges 12. Each second side 16 can have a third edge 17 vertical to the first edge 12 and the second edge 14. Two parallel first edges 12 and two parallel third edges 17 can be coupled to each other in an order to form the light emitting surface 11. The second edges 14 and the third edges 17 can have a same length, thus the second sides 16 can be square in shape. The reflective cup 10 can encapsulate the LED chip, and the light emitted from the LED chip can emit outside of the reflective cup 10 via the light emitting surface 11.

The positive electrode plate 30 can be positioned on the reflective cup 10 and electrically coupled to the LED chip. The positive electrode plate 30 can be substantially L-shaped, and include a first weld 32, a first bent portion 34, and a second weld 36. The first weld 32 can be substantially a rectangular plate, positioned on one first side 15, and electrically coupled to the LED chip. The second weld 34 can be substantially a rectangular plate, and positioned on the bottom surface 13. The bent portion 34 can be electrically coupled to the first weld 32 and the second weld 36. In at least one embodiment, the first weld 32, the second weld 36, and the first bent portion 34 can be integrated, for example, the positive electrode plate 30 can be made of a flexible flat electrode which can be bent to an L-shaped plate.

The structure of the negative electrode plate 50 can be substantially the same as that of the positive electrode plate 30. The negative electrode plate 50 can be positioned on the reflective cup 10, electrically coupled to the LED chip, and spaced a predetermined distance from the positive electrode plate 30. The negative electrode plate 50 can be insulated from the positive electrode plate 30.

The negative electrode plate 50 can be substantially L-shaped, and include a third weld 52, a second bent portion 54, and a fourth weld 56. The third weld 52 can be substantially a rectangular plate, positioned on one first side 15, and electrically coupled to the LED chip. The third weld 52 and the first weld 32 can be positioned on the same side 15, and spaced away from each other. The fourth weld 54 can be substantially a rectangular plate, positioned on the bottom surface 15, and spaced away from the second weld 36. The bent portion 54 can be electrically coupled to the third weld 52 and the fourth weld 56. In at least one embodiment, the third weld 52, the fourth weld 56, and the second bent portion 54 can be integrated, for example, the negative electrode plate 50 can be made of a flexible flat electrode which can be bent to an L-shaped plate.

A width of the first weld 32 along the second edge 14, the width of the second weld 36 along the third edge 17, the width of the third weld 52 along the second edge 14, and the width of the fourth weld 56 along the third edge 14, can be equal to each other. In at least one embodiment, the first weld 32, the second weld 36, the third weld 52, and the fourth weld 56 can have a different width from each other, so long as the first weld 32 and the third weld 52 are spaced and positioned on one first side 15, the second weld 36 and the fourth weld 56 are spaced and positioned on the bottom surface 13.

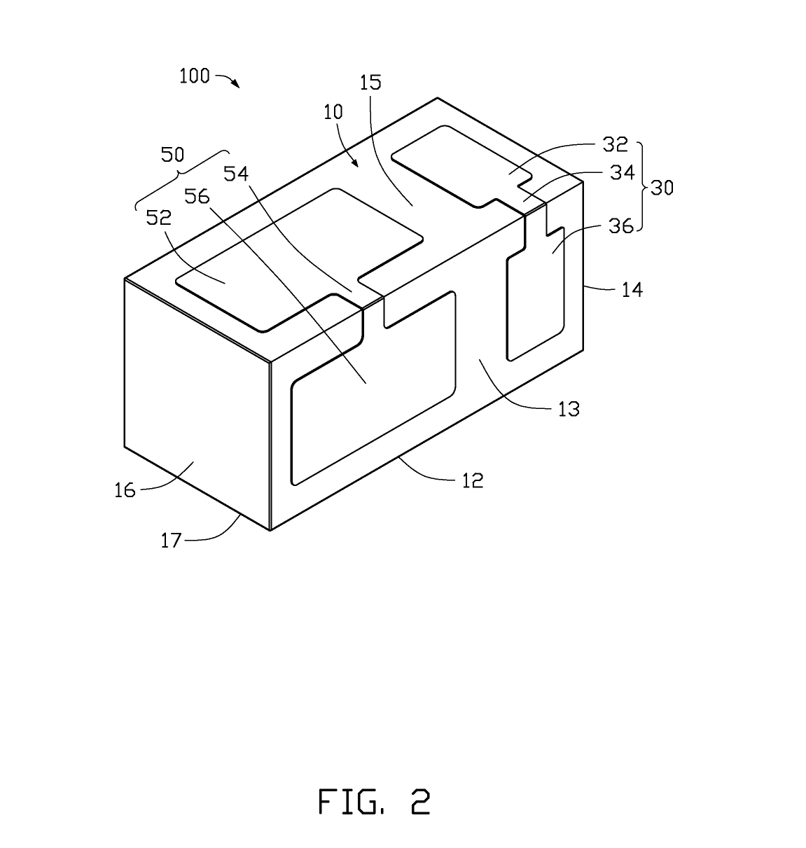

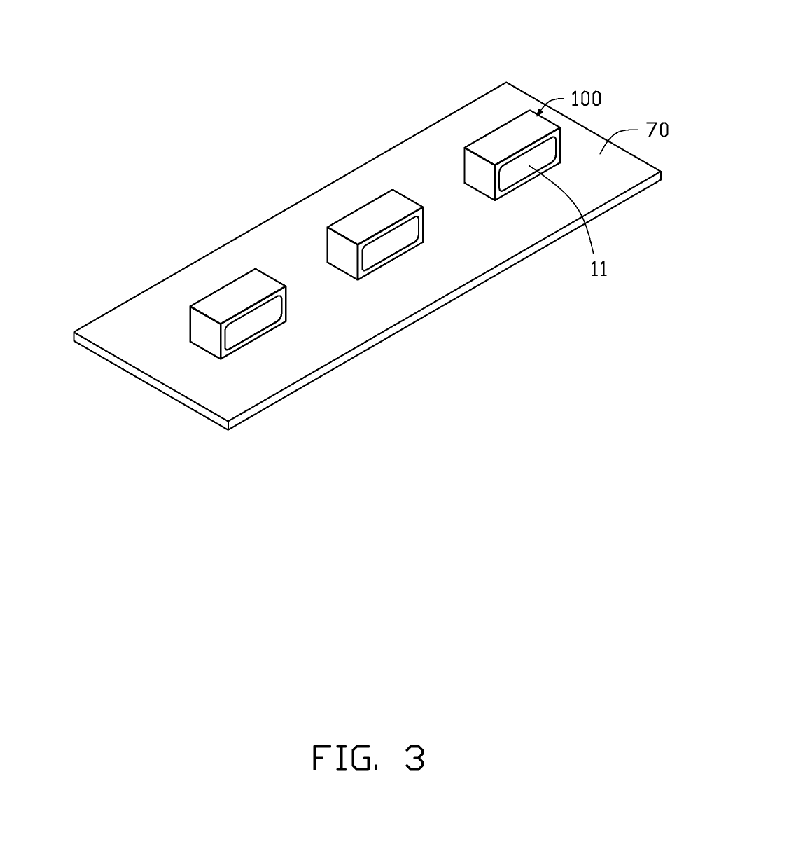

FIGS. 2 and 3 illustrate when in use, the first weld 32 and the third weld 52 can be welded to the PCB 70 by a reflow soldering method, and the PCB 70 can be electrically coupled to the LED chip (not shown). In this way, the light emitting surface 11 of the reflective cup 10 can be vertical to the surface of the PCB 70. Thus the LED encapsulation structure 100 can realize a side-emitting function.

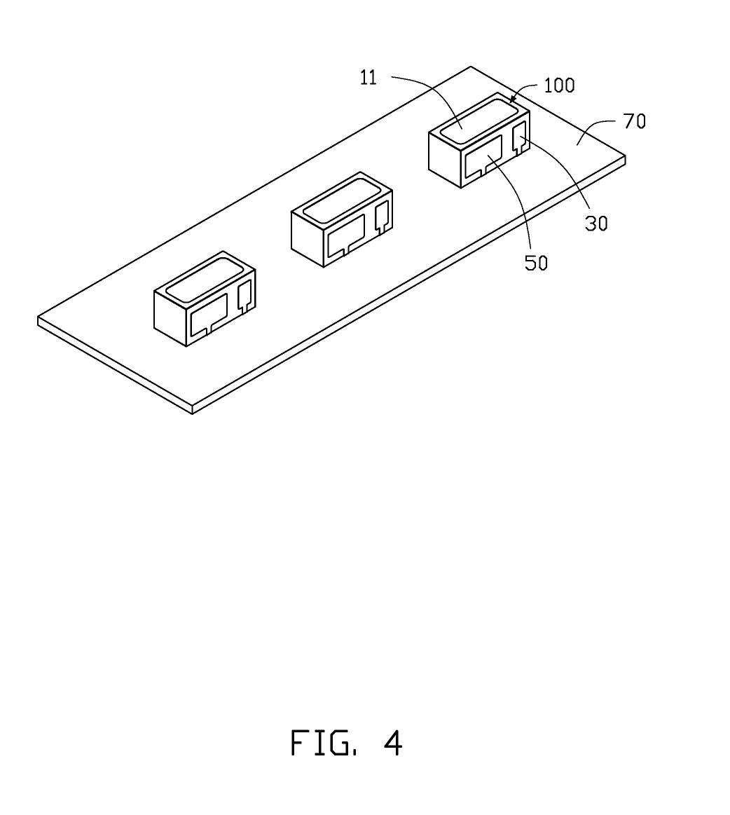

FIGS. 2 and 4 illustrate when in use, the second weld 36 and the fourth weld 56 can be welded to the PCB 70 by the reflow soldering method, and the PCB 70 can be electrically coupled to the LED chip (not shown). In this way, the light emitting surface 11 of the reflective cup 10 can be parallel to the surface of the PCB 70, thus the LED encapsulation structure 100 can realize a top-emitting function. Because the second sides 16 of the reflective cup 10 are square, the center of gravity of the LED encapsulation structure 100 is stable to holds to the LED encapsulation structure 100 during reflow soldering.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure, as defined by the appended claims.

What is claimed is:

1. An LED encapsulation structure comprising:
a reflective cup having a light emitting surface, a bottom surface opposite to the light emitting surface, two parallel first sides interconnecting with the light emitting surface and the bottom surface, and two parallel second sides interconnecting with the light emitting surface, the bottom surface and two the first sides;
a positive electrode plate positioned on the reflective cup, and comprising:
a first weld positioned on one first side,
a second weld positioned on the bottom surface, and
a first bent portion interconnecting with the first weld and the second weld; and
a negative electrode plate positioned on the reflective cup, spaced from the positive electrode plate, and comprising:
a third weld positioned on the same first side as the first weld and spaced from the first weld,
a fourth weld positioned on the bottom surface and spaced from the second weld, and
a second bent portion interconnecting with the third weld and the fourth weld.

2. The LED encapsulation structure of claim 1, wherein the two second sides are square.

3. The LED encapsulation structure of claim 1, wherein the first weld, the second weld, and the first bent portion are integrated.

4. The LED encapsulation structure of claim 3, wherein the positive electrode plate is made of flexible materials.

5. The LED encapsulation structure of claim 1, wherein the third weld, the second bent portion, and the fourth weld are integrated.

6. The LED encapsulation structure of claim 5, wherein the negative electrode plate is made of flexible materials.

7. The LED encapsulation structure of claim 1, wherein the first weld, the second weld, the third weld, and the fourth weld are welded to a printed circuit board by a reflow soldering method.

8. The LED encapsulation structure of claim 1, wherein each first side has two parallel first edges and two parallel second edges, each second side has two parallel third edges interconnecting with two adjacent first edge and second edge, two first edges and two third edges are coupled to each other to form the light emitting surface; a width of the first weld along the second edge, the width of the second weld along the third edge, the width of the third weld along the second edge, and the width of the fourth weld along the third edge are equal to each other.
